(19) United States
(12) Patent Application Publication
(10) Pub. No.: US 2026/0140337 A1
(43) Pub. Date: May 21, 2026

(54) PACKAGE STRUCTURE AND PACKAGE METHOD

(71) Applicant: STATS ChipPAC Semiconductor (Jiangyin) Co., LTD., Jiangyin (CN)

(72) Inventors: Jeonghan KIM, Jiangyin (CN); Soo Won LEE, Jiangyin (CN); Jian XU, Jiangyin (CN); Hyoungill MIN, Jiangyin (CN); Ruixin LI, Jiangyin (CN)

(21) Appl. No.: 19/385,730

(22) Filed: Nov. 11, 2025

(30) Foreign Application Priority Data
Nov. 15, 2024 (CN) 202411642591.2

(51) Int. Cl. G02B 6/42; H01L 25/18

(52) U.S. Cl. CPC G02B 6/4243; G02B 6/4206; G02B 6/4212; G02B 6/4239; G02B 6/4257; H10W 90/00

(57) ABSTRACT

A package structure and a package method are provided. The package structure includes: a photonic interposer configured to be integrated with a photonic device, where a first surface of the photonic interposer includes an optical coupling area; a chip bonded on the first surface and arranged spaced apart from the optical coupling area, where the chip is electrically connected to the photonic interposer; a protective ring located on the first surface and surrounding the optical coupling area, where the protective ring includes a cavity exposing the optical coupling area; and a molding layer located on the first surface, on a side of the chip, and outside of the cavity, wherein the molding layer covers side walls of the chip and outer walls of the protective ring.

### CROSS-REFERENCE TO RELATED APPLICATIONS

This application claims the benefit of priority to Chinese Application No. 202411642591.2, filed Nov. 15, 2024, which is incorporated herein by reference in its entirety.

### TECHNICAL FIELD

The present application relates to the field of semiconductor package, and particularly relates to a package structure and a package method.

### BACKGROUND

As demand for network and computational bandwidth continues to grow, the manner of interconnection using copper is approaching its bandwidth limit. Silicon photonics has become critical for sustaining high-bandwidth application areas such as rapid data growth, artificial intelligence (AI) learning, high performance computing (HPC), etc.

### SUMMARY

The embodiment of the present disclosure provides a package structure, which includes: a photonic interposer integrated with a photonic device, a first surface of the photonic interposer having an optical coupling area; a chip bonded on the first surface and arranged spaced apart from the optical coupling area, the chip being electrically connected with the photonic interposer; a protective ring located on the first surface and surrounding the optical coupling area, the protective ring having a cavity exposing the optical coupling area; and a molding layer located on the first surface on a side of the chip and the outside of the cavity, the molding layer covering the side walls of the chip and the outer walls of the protective ring.

Accordingly, the embodiment of the present disclosure further provides a package method, which includes: providing a photonic interposer integrated with a photonic device, a first surface of the photonic interposer having an optical coupling area; bonding a chip on the first surface, the chip being arranged spaced apart from the optical coupling area, the chip being electrically connected with the photonic interposer; arranging, on the first surface, a cap covering over the optical coupling area, the cap having a cavity, and the projection of the cavity on the photonic interposer covers the optical coupling area; forming a molding layer on the first surface on a side of the chip and on a side of the cap, the molding layer covering the side walls of the chip and the side walls of the cap; and after forming the molding layer, thinning the cap to expose the cavity.

### BRIEF DESCRIPTION OF THE DRAWINGS

FIG. 1 is a structural schematic diagram of a package structure;

FIG. 2 is a top view schematic diagram of an embodiment of the package structure of the present disclosure;

FIG. 3 is a cross-sectional schematic diagram of FIG. 2 at position B1-B2;

FIGS. 4 to 21 are schematic diagrams corresponding to each step in an embodiment of the package method of the present disclosure; and

FIGS. 22 to 24 are schematic diagrams corresponding to each step in another embodiment of the package method of the present disclosure.

### DETAILED DESCRIPTION

As known from the background, there are still high quality risks in current co-packaged optical structures. Now, in conjunction with a package structure, the reasons why there are still high quality risks in co-packaged optical structures are analyzed.

Wherein, co-packaged optics (CPO) technology is an advanced optical package technology, the co-packaged optical structure integrates optical devices and chips onto a single package substrate, which is intended to solve next-generation bandwidth and power issues. However, there are still higher quality risks associated with current co-packaged optical structures.

In the package structure provided by the embodiment of the present disclosure, a photonic device is integrated in a photonic interposer, and a first surface of the photonic interposer has an optical coupling area, and a protective ring surrounding the optical coupling area is arranged on the first surface of the photonic interposer, and the protective ring has a cavity exposing the optical coupling area, and a molding layer is located on a first surface of a side of the chip and the outside of the cavity, the molding layer covers the side walls of the chip and the outer walls of the protective ring; wherein the cavity exposes the optical coupling area, facilitating the installation of optical fiber structures through the cavity; furthermore, the protective ring serves to protect the optical coupling area, such that the probability of the molding layer contacting the optical coupling area is reduced, thereby reducing the probability of damage to the optical coupling area; meanwhile, by the molding layer covering the first surface, the probability of the occurrence of warping of the photonic interposer is reduced, which is conducive to improving the reliability of electrical connections between the photonic interposer and other circuit structures (e.g., the package substrate), as well as reducing the probability of cracking in the photonic interposer, thereby improving the quality of the package structure.

In the package method provided by the embodiment of the present disclosure, after providing a photonic interposer integrating a photonic device, a cap covering over the optical coupling area is arranged on a first surface of the photonic interposer, the cap having a cavity, and the projection of the cavity on the photonic interposer covers the optical coupling area, and a molding layer is formed on the first surface of a side of the chip and a side of the cap; after forming the molding layer, the cap is thinned to expose the cavity; wherein the cap covers the optical coupling area, which can serve to protect the optical coupling area when forming the molding layer, such that the probability of the molding layer contacting the optical coupling area is reduced, thereby reducing the probability of damage to the optical coupling area; furthermore, by thinning the cap to expose the cavity, it facilitates the installation of optical fiber structures through the cavity, meanwhile, by forming the molding layer covering the first surface, the probability of the occurrence of warping of the photonic interposer is reduced, which is conducive to improving the reliability of electrical connections between the photonic interposer and other circuit structures, as well as reducing the probability of cracking in the photonic interposer, thereby improving the quality of the package structure.

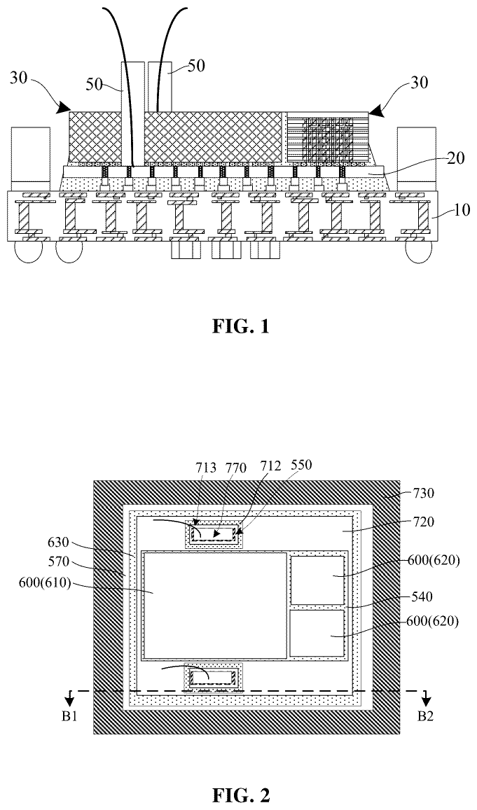

Referring to FIG. 1, FIG. 1 is a structural schematic diagram of a package structure.

The package structure includes: a package substrate 10; a photonic interposer 20 integrated with photonic devices, bonded on the package substrate 10 and electrically connected with the package substrate 10, the first surface (not labeled) of the photonic interposer 20 has an optical coupling area (not labeled); a chip 30 located on the first surface and arranged spaced apart from the optical coupling area, the chip 30 being electrically connected with the photonic interposer 20; and an optical fiber structure 50 mounted on the first surface and located in the optical coupling area.

In order to facilitate mounting the optical fiber structure 50 on the first surface, the package structure is typically an unmolded structure. However, due to the thinness of the photonic interposer 20 is small, warping tends to occur in an unmolded state, consequently, along the edges of the photonic interposer 20, the electrical connection reliability between the photonic interposer 20 and the package substrate 10 is poor (e.g., it is prone to cold solder joint problems), and the photonic interposer 20 is also prone to cracking, thereby resulting in higher quality risks for the package structure.

In order to solve the technical problem, in the package structure provided by the embodiment of the present disclosure, a protective ring surrounding the optical coupling area is arranged on the first surface of the photonic interposer, and the protective ring has a cavity exposing the optical coupling area, and a molding layer is located on a first surface of a side of the chip and the outside of the cavity, the molding layer covering the side walls of the chip and the outer walls of the protective ring; wherein the cavity exposes the optical coupling area, facilitating the installation of optical fiber structures through the cavity, furthermore, the protective ring can serve to protect the optical coupling area, such that the probability of the molding layer contacting the optical coupling area is reduced, thereby reducing the probability of damage to the optical coupling area, meanwhile, by the molding layer covering the first surface, the probability of the occurrence of warping of the photonic interposer is reduced, which is conducive to improving the reliability of electrical connections between the photonic interposer and other circuit structures, as well as reducing the probability of cracking in the photonic interposer, thereby improving the quality of the package structure.

In order to make the above objectives, features, and advantages of the embodiments of the present disclosure more obvious and understandable, specific embodiments of the present disclosure are described in detail below in conjunction with the accompanying drawings.

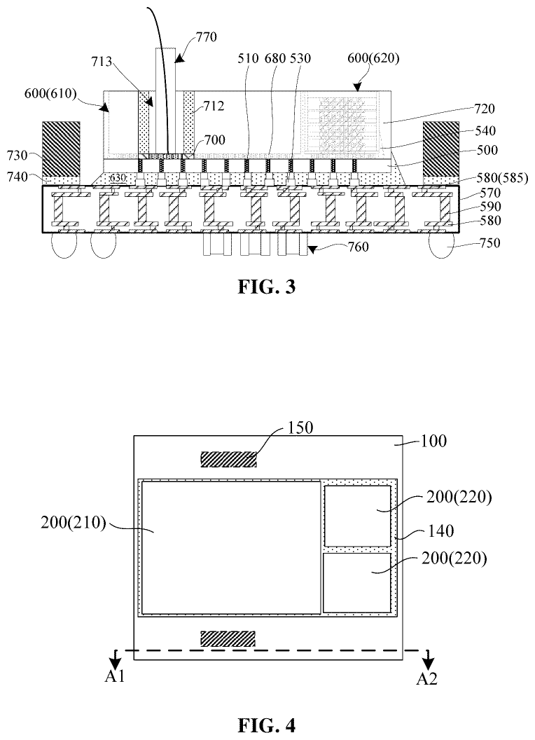

Referring to both FIGS. 2 and 3, FIG. 2 is a top view schematic diagram of an embodiment of the package structure of the present disclosure, FIG. 3 is a cross-sectional schematic diagram of FIG. 2 at position B1-B2.

The package structure includes: a photonic interposer 500 integrated with photonic devices, the first surface 500A of the photonic interposer 500 has an optical coupling area 550; a chip 600 bonded on the first surface 500A and arranged spaced apart from the optical coupling area 550, the chip 600 being electrically connected with the photonic interposer 500; a protective ring 712 located on the first surface 500A and surrounding the optical coupling area 550, the protective ring 712 having a cavity 713 exposing the optical coupling area; a molding layer 720 located on the first surface 500A of a side of the chip 600 and the outside of the cavity 713, the molding layer 720 covering the side walls of the chip 600 and the outer walls (not labeled) of the protective ring 712.

The photonic interposer 500 provides a process platform for the integration of chips, a chip 600 is arranged on the photonic interposer 500, so that the photonic interposer 500 is able to achieve the transmission of electrical and optical signals, and it enables the transmission of optical and electrical signals over shorter distances, thereby achieving efficient conversion and transmission of optoelectronic signals, and it is conducive to reducing power consumption, improving bandwidth, and thus obtaining highly integrated co-packaged optical structures, making the package structure suitable for high performance computing and other applications with high-speed optical communication requirements.

Photonics devices are used to form a photonic integrated circuit (PIC).

It should be noted that the photonics devices in the photonic interposer 500 include, but are not limited to one or more of lasers, photodetectors, waveguides, optical couplers, optical modulators, and optical filters.

As an example, the photonic interposer 500 is made from silicon-based materials, therefore the photonic interposer 500 is a silicon photonic interposer. In other embodiments, the base material of the photonic interposer may be selected from other materials to meet different functional and performance requirements; for example, the base material of the photonic interposer may be indium phosphide (InP), gallium arsenide (GaAs), lithium niobate (LiNbO₃), etc.

The optical coupling area 550 of the photonic interposer 500 is the core area for achieving efficient transmission of optical signals, it is used for achieving optical communication with optical fiber structures.

In the present embodiment, the photonic interposer 500 has a first interconnection structure 510, which enables the photonic interposer 500 to achieve the transmission of electrical signals.

In one embodiment, the first interconnection structure 510 includes interconnection through-via structures running through the photonic interposer 500, thereby improving the speed of signal transmission through the way of vertical electrical interconnecting. In other embodiments, the first interconnection structure may also include multilayer interconnection lines and interconnection through-via structures for connecting interconnection lines of adjacent layers.

In one embodiment, the material of the first interconnection structure 510 includes copper. It is can be understood that the first interconnection structure may also be of other conductive materials, such as tungsten.

In the present embodiment, the photonic interposer 500 further includes a second surface 500B arranged facing away from the first surface 500A.

The chip 600 is used to provide electronic devices, thereby achieving functions such as data processing, signal processing, data storage, driving photonic devices, etc. By integrating the chip 600 and the photonic interposer 500 in a same package structure, a highly integrated optoelectronic system is achieved.

The specific type of chip 600 can be selected according to actual requirements, for example, chip 600 may include one or more of an Application-Specific Integrated Circuit (ASIC) chip, a High Bandwidth Memory (HBM) chip, a Central Processing Unit (CPU) chip, a Graphics Processing Unit (GPU) chip, and a Field-Programmable Gate Array (FPGA) chip.

As an example, chip 600 includes an ASIC chip 610 and an HBM chip 620. By integrating the ASIC chip 610 and the HBM chip 620 on the photonic interposer 500, a more compact, efficient, and high-performance optoelectronic integrated system can be achieved, thereby meeting the requirements of high performance computing and big data processing.

It should be noted that FIG. 2 only illustrates three chips 600 and one arrangement of three chips 600, but the number of chips 600 is not limited to three, and other arrangements of chips 600 may also be used.

In the present embodiment, chip 600 is bonded on the photonic interposer 500 through a flip chip process, thereby improving communication speeds between optoelectronic devices.

For this purpose, the package structure further includes: a first conductive connection element 680 located between the chip 600 and the photonic interposer 500, and the first conductive connection element 680 electrically connects the first interconnection structure 510 in the photonic interposer 500 with the chip 600.

The first conductive connection element 680 may be a bump. For example, the first conductive connection element 680 may be a microbump (μBump) or a C2 bump. Wherein a C2 bump typically refers to a copper pillar bump with its top surface having a solder cap.

The first conductive connection element 680 may be made of a material with good electrical conductivity, such as one or more of copper, aluminum, gold, nickel, silver, palladium, and tin.

In the present embodiment, the package structure further includes: a first underfill layer 540 located between the photonic interposer 500 and the chip 600, the first underfill layer 540 also covering the sidewalls of the first conductive connection element 680.

By filling the gap between the chip 600 and the photonic interposer 500 with the first underfill layer 540, it is conductive to improving the bonding strength between the chip 600 and the photonic interposer 500, and it is also conductive to protecting the first conductive connection element 680.

As an example, the material of the first underfill layer 540 includes epoxy resin, so that it can serve for mitigating stress impact.

In the present embodiment, the first underfill layer 540 is also filled between adjacent chips 600, so that it further serves for reinforcing and protecting the chips 600.

In other embodiments, the chips may be bonded on the photonic interposer using other suitable bonding processes, such as metal direct bonding or metal oxide hybrid bonding and other processes.

The protective ring 712 surrounds the optical coupling area 550, it can serve for protecting the optical coupling area 550 such that the probability of the molding layer 720 contacting the optical coupling area 550 is reduced, thereby reducing the probability of damage to the optical coupling area 550, thus improving the quality of the package structure.

Moreover, the cavity 713 in the protective ring 712 exposes the optical coupling area 550, so that it is easy to achieve the installation of the optical fiber structure through the cavity 713. Additionally, the cavity 713 serves as an installation window for the optical fiber structure, which is conductive to improving alignment accuracy between the optical fiber structure and the optical coupling area 550.

In the present embodiment, the projection shape of cavity 713 on the first surface 500A is square. However, the projection shape of cavity 713 is not limited to square. In other embodiments, the projection shape of the cavity on the first surface may also be circular, octagonal, irregularly shape, etc.

In the present embodiment, the shape of the protective ring 712 is square ring shape. However, the shape of protective ring 712 is not limited to square. In other embodiments, the protective ring may also be circular, octagonal, irregularly shape, etc.

It should be noted that the protective ring 712 includes an inner wall (not labeled) facing the optical coupling area 550 and an outer wall facing away from the optical coupling area 550, the inner wall of the protective ring 712 surrounds the cavity 713.

The material of the protective ring 712 may include one or more of metal, epoxy molding compound (EMC), ceramic, and silicon, thereby improving compatibility with the package process.

In the present embodiment, the material of the protective ring 712 is epoxy molding compound, which improves the bonding strength between the protective ring 712 and the molding layer 720, and also helps to reduce the preparation cost of the protective ring 712. In other embodiments, the material of the protective ring may also be metal, which improves the strength of the protective ring, and it is also easy to achieve heat dissipation through metal protective rings.

In the present embodiment, the package structure further includes: a connection layer 700 located between the first surface 500A and the protective ring 712. The connection layer 700 is used to fix the protective ring 712 on the first surface 500A, and improve the bonding strength between the protective ring 712 and the photonic interposer 500.

In the present embodiment, the connection layer 700 may include an epoxy resin layer or an adhesive layer, thereby reducing the complexity of fixing the protective ring 712 on the first surface 500A. Wherein the adhesive layer has viscosity, so that it can fix the protective ring 712 on the first surface 500A; in some embodiments, after the protective ring 712 contacting uncured epoxy resin, the protective ring 712 also can be fixed on the first surface 500A by curing the epoxy resin.

It should be noted that the material of the adhesive layer includes silicone-based adhesive layer, polyimide-based adhesive layer, epoxy resin-based adhesive layer, or polyurethane-based adhesive layer.

It should also be noted that when the material of the protective ring 712 is metal, a thermally conductive adhesive layer may be selected to improve the heat dissipation performance of the package structure.

The molding layer 720 is used to protect the chip 600 and the photonic interposer 500, and package the chip 600 and the photonic interposer 500 into a single package.

In the present embodiment, the material of the molding layer 720 is a molding material, such as epoxy resin. Epoxy resin has the advantages of low shrinkage, good adhesion, good corrosion resistance, excellent electrical performance, relatively low cost, etc. In other embodiments, the molding layer may also select other suitable package materials.

Wherein by the molding layer 720 covering the first surface 500A, the probability of the occurrence of warping in the photonic interposer 500 is reduced, which is conducive to improving the reliability of electrical connections between the photonic interposer 500 and other circuit structures (e.g., the package substrate), as well as reducing the probability of cracking in the photonic interposer 500, thereby improving the quality of the package structure.

In the present embodiment, the top of the molding layer 720, the top of the protective ring 712, and the top of the chip 600 are all flush with each other, which is not only helpful to reduce the thickness of the package structure but also enables that the top of the chip 600 is exposed by the molding layer 720, which is conducive to improving the heat dissipation performance of the chip 600.

In the present embodiment, the package structure further includes a package substrate 570. The package substrate 570 is used to provide a process platform for the package of the photonic interposer 500 and the chip 600, and the package substrate 570 has in it circuits, so that the package substrate 570 can serve for power supply or electrical signal transmission.

Accordingly, the second surface 500B of the photonic interposer 500 is bonded on the package substrate 570, the photonic interposer 500 being electrically connected with the package substrate 570.

In the present embodiment, the package substrate 570 has in it a second interconnection structure (not labeled) to achieve electrical connection between the package substrate 570 and the photonic interposer 500.

In one embodiment, the second interconnection structure includes multiple interconnection lines 580 and through-via interconnection structures 590 for connecting interconnection lines 580 of adjacent layers. It should be noted that the interconnection lines 580 exposed on the surface of the package substrate 570 may be used as solder pads.

In other embodiments, the second interconnection structure may include interconnection through-via structures running through the package substrate.

In the present embodiment, the package structure further includes: a second conductive connection element 530 located between the photonic interposer 500 and the package substrate 570, the second conductive connection element 530 electrically connects the photonic interposer 500 with the package substrate 570. In some embodiments, the second conductive connection element 530 electrically connects the first interconnection structure 510 in the photonic interposer 500 and the second interconnection structure in the package substrate 570.

The second conductive connection element 530 may include solder bump, metal pillar, controlled collapse chip connection (C4) bump, the second conductive connection element 530 may include conductive materials, for example, it may include one or more of copper, aluminum, gold, nickel, silver, palladium, and tin. As an example, the second conductive connection element 530 is a C4 bump.

In the present embodiment, the package structure further includes: a second underfill layer 630 located between the photonic interposer 500 and the package substrate 570, the second underfill layer 630 further covering the sidewalls of the second conductive connection element 530.

By filling the gap between the photonic interposer 500 and the package substrate 570 with the second underfill layer 630, it is conductive to improving the bonding strength between the photonic interposer 500 and the package substrate 570, and it is also conductive to protecting the second conductive connection element 530.

As an example, the material of the second underfill layer 630 includes epoxy resin, so that it can serve for mitigating stress impact.

In the present embodiment, the package structure further includes: an optical fiber structure 770, which is installed in the cavity 713.

The optical fibers in the optical fiber structure 770 are coupled with the photonic devices in the photonic interposer 500 to achieve optical communication. As an example, the optical fiber structure 770 may be fixed on the pad area in the optical coupling area 550 through an adhesive layer (e.g., optical adhesive).

As an example, the optical fiber structure 770 may be an optical fiber array unit (FAU).

In the present embodiment, the package structure further includes: a stiffener ring 730 located on the package substrate 570 and surrounding the photonic interposer 500.

The stiffener ring 730 helps to reduce the probability of the occurrence of warping problems in the package substrate 570 and also conductive to improving the mechanical strength of the package structure; furthermore, the stiffener ring 730 surrounds the photonic interposer 500, accordingly, it is also beneficial to provide certain protection for the photonic interposer 500 and the chip 600.

As an example, the stiffener ring 730 is located at the edge of the package substrate 570, thereby enhancing the effect of improving the warping problem and providing sufficient space for the installation of the photonic interposer 500.

As an example, the projection shape of the stiffener ring 730 on the package substrate 570 is square. In other embodiments, the projection shape of the stiffener ring may also be other shapes (e.g., circular, octagonal, etc.).

In the present embodiment, the material of the stiffener ring 730 includes metal. The stiffener ring 730 using metal material also helps to improve the heat dissipation performance of the package structure. As an example, the material of the stiffener ring 730 may include copper, iron, nickel, stainless steel, nickel-iron alloy, etc.

In the present embodiment, the connection layer 700 located between the first surface 500A and the protective ring 712 serves as the first connection layer, and the package structure further includes a second connection layer 740 located between the stiffener ring 730 and the package substrate 570.

The second connection layer 740 is used to fix the stiffener ring 730 on the package substrate 570 and improve the bonding strength between the stiffener ring 730 and the package substrate 570.

In the present embodiment, the second connection layer 740 may be an adhesive layer. The material of the adhesive layer includes silicon-based adhesive layer, polyimide-based adhesive layer, epoxy-based adhesive layer, or polyurethane-based adhesive layer.

As an example, the material of the stiffener ring 730 is metal, so that the second connection layer 740 may be a thermally conductive adhesive layer, thereby improving the heat dissipation performance of the package structure.

In the present embodiment, the package structure may further include: a third conductive connection element 750 located on the surface of the package substrate 570 facing away from the photonic interposer 500, the third conductive connection element 750 being electrically connected with the package substrate 570.

The third conductive connection element 750 is used to achieve electrical connection between the package substrate 570 and other external circuits. For example, the package substrate 570 is subsequently assembled onto a Printed Circuit Board (PCB) through the third conductive connection element 750.

In the present embodiment, the third conductive connection element 750 is a bump, such as a solder ball. The third conductive connection element 750 may be made of a material with good electrical conductivity, for example, it may include one or more of copper, aluminum, gold, nickel, silver, palladium, and tin.

In the present embodiment, the package structure may further include a passive device 760 bonded on the surface of the package substrate 570 facing away from the photonic interposer 500. By integrating the passive device 760 in the package structure, it is conductive to improving the performance of the package structure.

The passive device 760 may include capacitors, inductors, resistors, etc., thereby playing a specific role in the operation of optoelectronic system.

It should be noted that the passive device 760 is located on the surface of package substrate 570 facing away from photonic interposer 500, which can fully utilize the area of the package substrate 570 and help to reduce the lateral dimensions of the package structure.

Accordingly, the present disclosure also provides a package method for the package structure. FIGS. 4 to 21 are schematic diagrams corresponding to each step in an embodiment of the package method of the present disclosure.

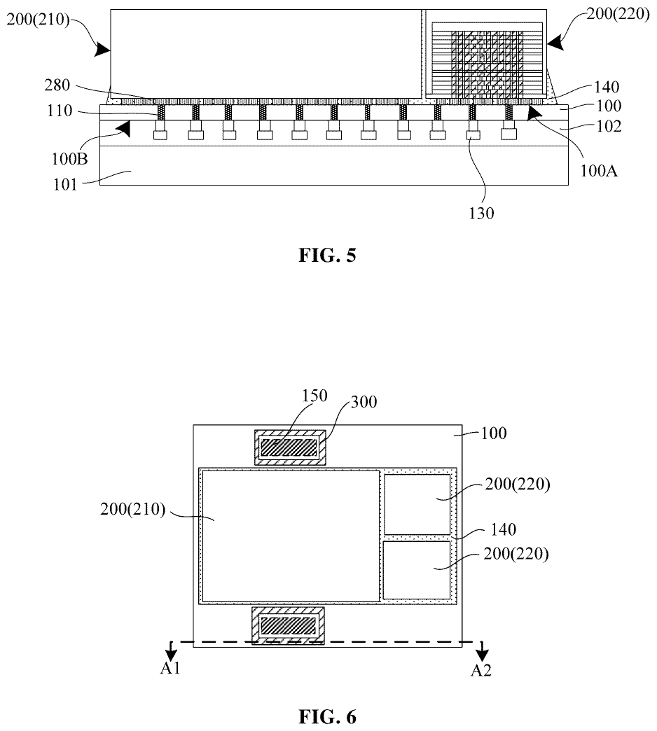

Referring to FIGS. 4 and 5, FIG. 4 is a top view schematic diagram, and FIG. 5 is a cross-sectional schematic diagram of FIG. 4 at position A1-A2, a photonic interposer 100 integrated with photonic devices is provided, the first surface 100A of the photonic interposer 100 has an optical coupling area 150.

The photonic interposer 100 provides a process platform for the integration of chips, a chip is arranged on the photonic interposer 100, so that the photonic interposer 100 is able to achieve the transmission of electrical and optical signals, and it enables the transmission of optical and electrical signals over shorter distances, thereby achieving efficient conversion and transmission of optoelectronic signals, and it is conducive to reducing power consumption, improving bandwidth, and thus obtaining highly integrated co-packaged optical structures, making the package structure suitable for high performance computing and other applications with high-speed optical communication requirements.

It should be noted that the photonics devices in the photonic interposer 100 include, but are not limited to one or more of lasers, photodetectors, waveguides, optical couplers, optical modulators, and optical filters.

As an example, the photonic interposer 100 is a silicon photonic interposer. In other embodiments, the base material of the photonic interposer 500 may further be selected from other materials.

The optical coupling area 150 of the photonic interposer 100 is the core area for achieving efficient transmission of optical signals, it is used for achieving optical communication with optical fiber structures.

In the present embodiment, the photonic interposer 100 has a first interconnection structure 110, so that it is able to enable the photonic interposer 100 to achieve the transmission of electrical signals.

In one embodiment, the first interconnection structure 110 includes interconnection through-via structures running through the photonic interposer 100. In other embodiments, the first interconnection structure may also include multilayer interconnection lines and interconnection through-via structures for connecting interconnection lines of adjacent layers.

In one embodiment, the material of the first interconnection structure 110 includes copper. It can be understood that the first interconnection structure may also be of other conductive materials, such as tungsten.

In the present embodiment, the photonic interposer 100 further includes a second surface 100B arranged facing away from the first surface 100A.

In the present embodiment, a second conductive connection element 130 is formed on the second surface 100B of the photonic interposer 100, the second conductive connection element 130 being electrically connected with the first interconnection structure 110.

Subsequently, the photonic interposer 100 is bonded onto the package substrate through the second conductive connection element 130.

The second conductive connection element 130 may include solder bump, metal pillar, or controlled collapse chip connection bump, the second conductive connection element 130 may include conductive materials, for example it may include one or more of copper, aluminum, gold, nickel, silver, palladium, and tin. As an example, the second conductive connection element 130 is a C4 bump.

In the present embodiment, the photonic interposer 100 is temporarily bonded on the carrier board 101, the first surface 100A of the photonic interposer 100 faces away from the carrier board 101.

The carrier board 101 can provide support for the photonic interposer 100 during subsequent package steps, which is conductive to reducing the probability of the occurrence of warping or cracking in the photonic interposer 100.

In the present embodiment, the carrier board 101 is a glass carrier board. In other embodiments, the carrier board may also be a silicon carrier board or a carrier board made of other materials.

As an example, the photonic interposer 100 may be temporarily bonded on the carrier board 101 through a temporary bonding layer 102. The temporary bonding layer 102 serves as a release layer, facilitating the subsequent separation of the photonic interposer 100 and the carrier board 101.

Continuing with reference to FIGS. 4 and 5, a chip 200 is bonded on the first surface 100A, the chip 200 is arranged spaced apart from the optical coupling area 150, the chip 200 being electrically connected with the photonic interposer 100.

The chip 200 is used to provide electronic devices, thereby achieving functions such as data processing, signal processing, data storage, driving photonic devices, etc.

The specific type of chip 200 can be selected according to actual requirements, for example, chip 200 may include one or more of an ASIC chip, an HBM chip, a CPU chip, a GPU chip, and an FPGA chip.

As an example, chip 200 includes an ASIC chip 610 and an HBM chip 620, so that a more compact, efficient, and high-performance optoelectronic integrated system can be achieved, thereby meeting the requirements of high performance computing and big data processing.

In the present embodiment, chip 200 is bonded on the photonic interposer 100 through a flip chip process, thereby improving communication speeds between optoelectronic devices.

In some embodiments, chip 200 is bonded on first surface 100A using the first conductive connection element 280, after bonding is performed, the first conductive connection element 280 is located between chip 200 and the photonic interposer 100, the first conductive connection element 280 electrically connects the first interconnection structure 110 in the photonic interposer 100 with the chip 200.

The first conductive connection element 280 may be a bump. For example, the first conductive connection element 280 may be a microbump or a C2 bump. The first conductive connection element 280 may be made of a material with good electrical conductivity, for example, it may include one or more of copper, aluminum, gold, nickel, silver, palladium, and tin.

In the present embodiment, after bonding the chip 200 on the first surface 100A, the package method further includes: forming a first underfill layer 140 between the photonic interposer 100 and the chip 200, the first underfill layer 140 also covering the sidewalls of the first conductive connection element 280.

As an example, the material of the first underfill layer 140 includes epoxy resin.

In the present embodiment, the first underfill layer 140 is also filled between adjacent chips 200, thereby further reinforcing and protecting the chips 200.

In other embodiments, the chips may also be bonded on the photonic interposer using other suitable bonding processes, such as metal direct bonding or metal oxide hybrid bonding and other techniques.

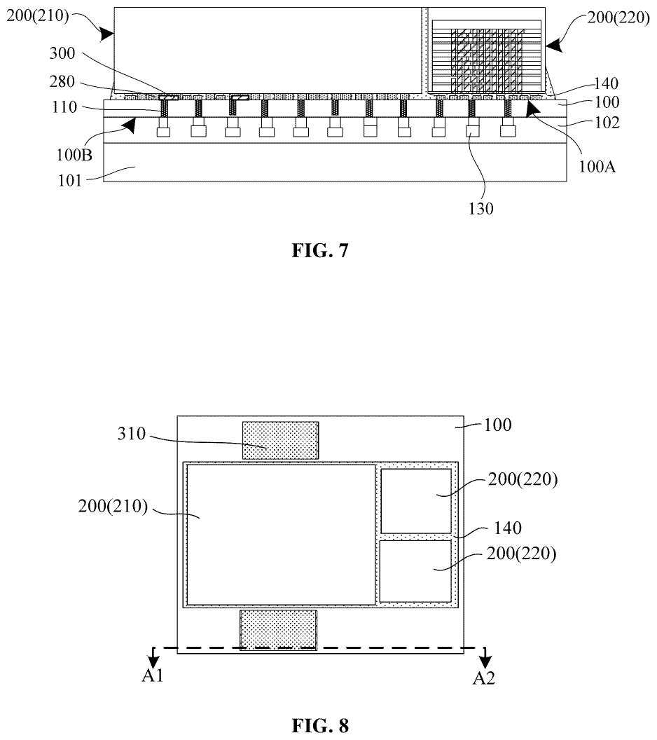

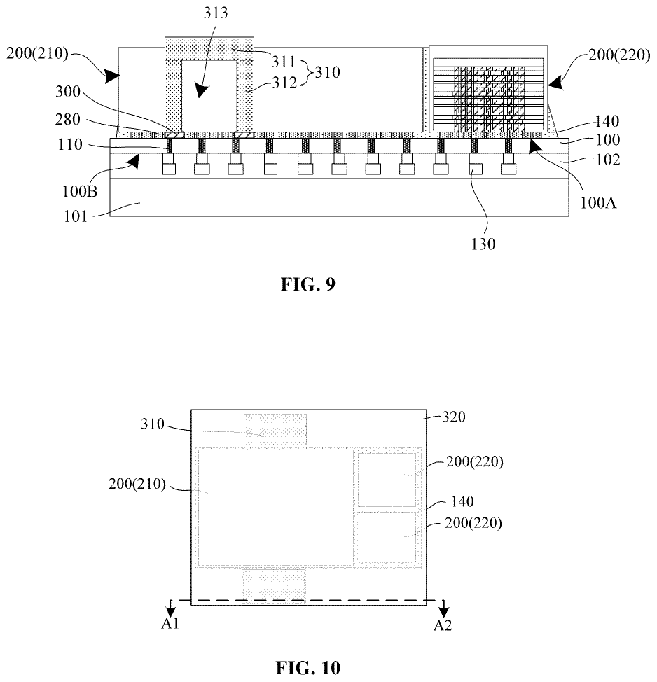

Referring to FIGS. 6 to 9, FIG. 6 is a top view schematic diagram based on FIG. 4, FIG. 7 is a cross-sectional schematic diagram of FIG. 6 at position A1-A2, FIG. 8 is a top view schematic diagram based on FIG. 6, and FIG. 9 is a cross-sectional schematic diagram of FIG. 8 at position A1-A2, a cap 310 covering over the optical coupling area 150 is arranged on the first surface 100A, the cap 310 having a cavity 313, and the projection of cavity 313 on the photonic interposer 100 covers the optical coupling area 150.

The cap 310 shields the optical coupling area 150, which can serve for protecting the optical coupling area 150 during the subsequent formation of the molding layer, such that the probability of the package layer contacting the optical coupling area 150 is reduced, and the probability of damage to the optical coupling area 150 is reduced, thus improving the quality of the package structure.

Moreover, the cap 310 has a cavity 313, so that the probability of direct contact between the cap 310 and the optical coupling area 150 is reduced, thereby the probability of damage to the optical coupling area 150 caused by the cap 310 is reduced.

At the same time, the projection of cavity 313 on the photonic interposer 100 covers the optical coupling area 150, so that it is avoided that the cap 310 obstructs the optical coupling area 150, thereby reducing the complexity of exposing the optical coupling area 150, so that it is easy to achieve the installation of the optical fiber structure through the cavity 313.

Moreover, after subsequent exposure of the cavity 313, the cavity 313 can serve as an installation window for the optical fiber structure, which is conductive to improving alignment accuracy between the optical fiber structure and the optical coupling area 150.

The material of the cap 310 may include one or more of metal, epoxy molding compound, ceramic, and silicon, thereby improving compatibility with package processes.

In the present embodiment, the material of the cap 310 is epoxy molding compound, thereby improving the bonding strength between the cap 310 and the molding layer. In other embodiments, the material of the cap may also be metal, thereby improving the strength of the cap, and it facilitates heat dissipation through the metal cap.

It should be noted that the cap 310 includes an inner wall (not labeled) facing optical coupling area 150 and an outer wall facing away from optical coupling area 150, the inner wall of cap 310 enclosing the cavity 313.

In the present embodiment, the shape of the cap 310 is rectangular, and the cross-sectional shape of the cavity 313 is square, thereby reducing the difficulty of manufacturing the cap 310, and reducing the difficulty of exposing the optical coupling area 150 and assembling the optical fiber structure.

In other embodiments, the cap may also be of other types of shapes (e.g., cylindrical, frustum, irregular shapes, etc.), and the cavity may also be of other types of cross-sectional shapes (e.g., circular, irregular shapes, etc.).

In the present embodiment, the cap 310 includes a top cover 311 and a protective ring 312 located between top cover 311 and photonic interposer 100, the top cover 311 and the protective ring 312 enclosing the cavity 313.

The cavity 313 is sealed by the top cover 311, thereby providing a protective space for the optical coupling area 150.

In the present embodiment, in the step of arranging, on the first surface 100A, the cap 310 covering over the optical coupling area 150, the cap 310 is fixed on the first surface 100A using the connection layer 300 (as shown in FIGS. 6 and 7).

The connection layer 300 is used to fix the cap 310 on the first surface 100A and improve the bonding strength between the cap 310 and the photonic interposer 100.

In the present embodiment, the connection layer 300 may include an epoxy resin layer or an adhesive layer, thereby reducing the complexity of fixing the cap 310 on the first surface 100A. Wherein the adhesive layer has viscosity, so that the cap 310 can be fixed on the first surface 100A; in some embodiments, after contacting the cap 310 with uncured epoxy resin, the cap 310 may be fixed on first surface 100A by curing the epoxy resin.

It should be noted that the material of the adhesive layer includes silicone-based adhesive layer, polyimide-based adhesive layer, epoxy resin-based adhesive layer, or polyurethane-based adhesive layer.

It should also be noted that when the material of the cap 310 is metal, a thermally conductive material adhesive layer may be selected to improve the heat dissipation performance of the package structure.

In some embodiments, as shown in FIGS. 6 and 7, a connection layer 300 surrounding the optical coupling area 150 is formed on the first surface 100A; as shown in FIGS. 8 and 9, after forming the connection layer 300, the cap 310 is fixed on the connection layer 300.

The optical coupling area 150 is located on the photonic interposer 100, therefore, by forming the connection layer 300 on the photonic interposer, it is easy to improve the alignment accuracy between the connection layer 300 and the optical coupling area 150; moreover, the area of the photonic interposer 100 is larger, and forming the connection layer 300 on the photonic interposer 100 also makes it easy to reduce the difficulty of forming the connection layer 300.

In other embodiments, the connection layer may also be fixed on the first surface after forming the connection layer on the cap.

In the present embodiment, after arranging the chip 200 on the first surface 100A, a cap 310 covering over the optical coupling area 150 is arranged on the first surface 100A, so that it provides greater operational space for the bonding of the chip 200 and avoids that the bonding process of the chip 200 affects the bonding strength between the cap 310 and the photonic interposer 100.

It should be noted that the installation sequence of the chip 200 and the cap 310 may be changed according to actual requirements. In one embodiment, the cap may be installed first, and then the chip is bonded, thereby protecting the optical coupling area through the cap during the chip bonding process. In other embodiments, after bonding a partial number of the chips, the cap and the remaining number of chips may be installed sequentially.

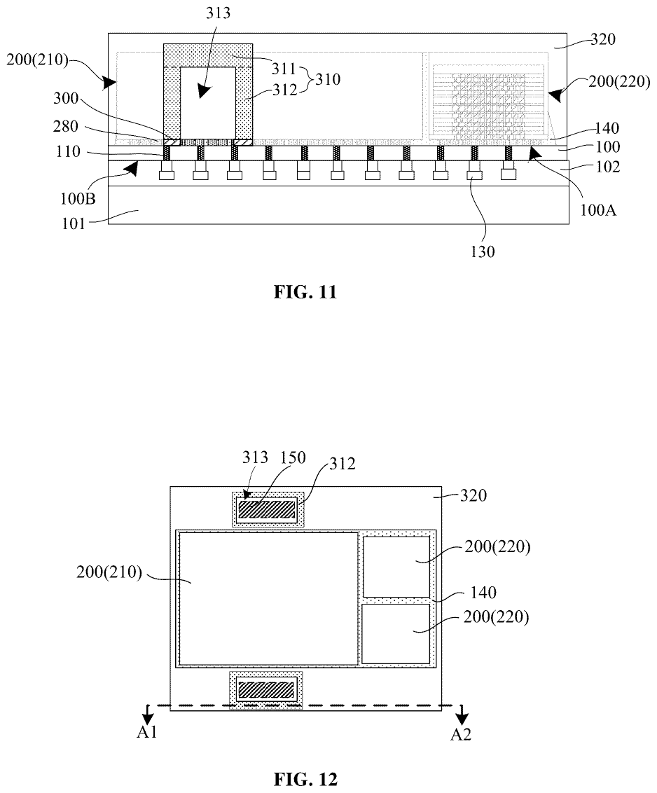

Referring to both FIGS. 10 to 11, FIG. 10 is a top view schematic diagram based on FIG. 8, and FIG. 11 is a cross-sectional schematic diagram of FIG. 10 at position A1-A2, a molding layer 320 is formed on the first surface 100A of the side of the chip 200 and the side of the cap 310, the molding layer 320 covering the side walls of the chip 200 and the side walls of the cap 310.

The molding layer 320 is used to protect the chip 200 and the photonic interposer 100, and to mold the chip 200 and the photonic interposer 100 into a single package. In the present embodiment, the material of the molding layer 320 is a package material, such as epoxy resin.

By the molding layer 320 covering the first surface 100A, the probability of the occurrence of warping in the photonic interposer 100 is reduced, which is conducive to improving the reliability of electrical connections between the photonic interposer 100 and other circuit structures (e.g., the package substrate), as well as reducing the probability of cracking in the photonic interposer 100, thereby improving the quality of the package structure. Moreover, the cap 310 is arranged covering above the optical coupling area 150, so that the molding layer 320 is formed outside the cavity 313.

In the present embodiment, in the step of forming the molding layer 320, the molding layer 320 covers the top of the chip 200 and the top of the cap 310, so that after subsequent thinning treatment, the top of the molding layer 320, the top of the remaining cap 310, and the top of the chip 200 are all flush with each other.

In the present embodiment, the top of cavity 313 is lower than the top of chip 200, i.e., the height of the lower surface of the top cover 311 is slightly lower than that of the top of chip 200, so that the thinning treatment of the cap 310 can be used to perform reduction of the partial thickness of the chip 200, which is conducive to reducing the thickness of the package structure and improving the heat dissipation performance of chip 200.

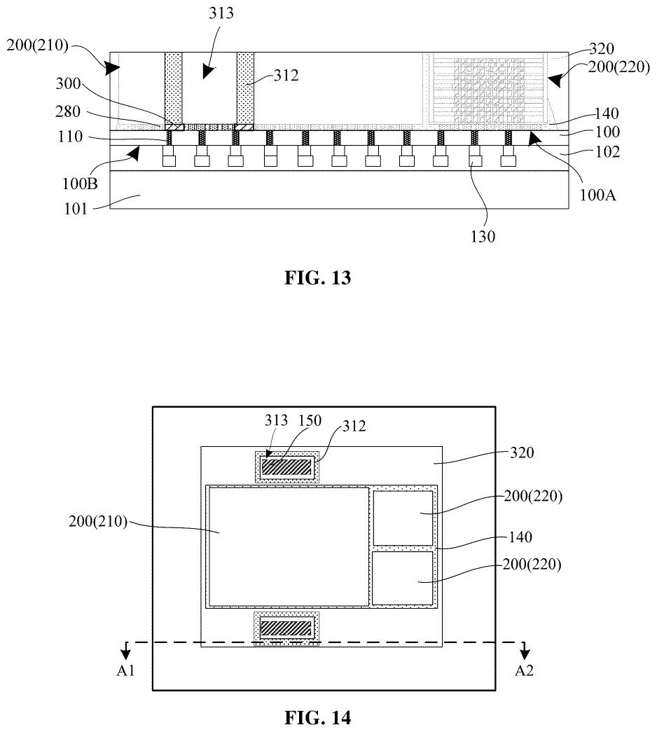

Referring to both FIGS. 12 to 13, FIG. 12 is a top view schematic diagram based on FIG. 10, and FIG. 13 is a cross-sectional schematic diagram of FIG. 12 at position A1-A2, after forming the molding layer 320, the cap 310 is thinned to expose the cavity 313.

Cavity 313 is exposed such that the optical coupling area 150 is exposed correspondingly through the cavity 313, thereby providing a process basis for subsequent assembly of optical fiber structures.

Because the cap 310 has cavity 313, the optical coupling area 150 can be exposed through thinning treatment without the need for etching the optical coupling area 150, thereby reducing the probability of damage to the optical coupling area 150.

In the present embodiment, in the step of thinning treatment of the cap 310 (as shown in FIG. 11), the top cover 311 (as shown in FIG. 11) is removed and the protective ring 312 is retained.

The protective ring 312 is retained, so that the protective ring 312 can continue to protect the optical coupling area 150.

In some embodiments, after forming the molding layer 320, the molding layer 320 and the cap 310 are sequentially thinned to expose the cavity 313 and the top of the molding layer 320 are made flush with the top of the chip 200.

Making the top of the molding layer 320 flush with the top of the chip 200 not only facilitates reduction of the thickness of the package structure but also enables the top of the chip 200 to be exposed through the molding layer 320, thereby improving the heat dissipation performance of the chip 200.

In the present embodiment, the top of cavity 313 is lower than the top of chip 200, therefore, during the thinning treatment, the chip 200 is also thinned. In other embodiments, the top of cavity 313 may be higher than the top of chip 200, so that the chip can undergo no thinning.

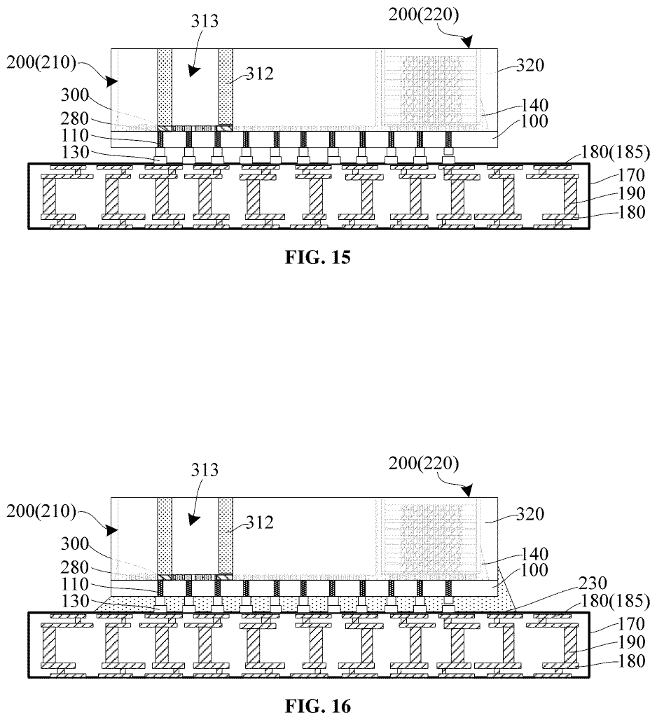

Referring to both FIGS. 14 and 15, FIG. 14 is a top view schematic diagram based on FIG. 12, FIG. 15 is a cross-sectional schematic diagram of FIG. 14 at position A1-A2; in the present embodiment, after exposing the cavity 313 and before installing the optical fiber structure in cavity 313, the package method further includes: bonding the second surface 100B of the photonic interposer 100 on the package substrate 170, the photonic interposer 100 being electrically connected with the package substrate 570.

The package substrate 170 is used to provide a process platform for the package of the photonic interposer 100 and the chip 200, and the package substrate 170 has in it circuits, so that the package substrate 170 can serve for power supply or electrical signal transmission.

In the present embodiment, the package substrate 170 has in it a second interconnection structure (not labeled) to achieve electrical connection between the package substrate 170 and the photonic interposer 100. In one embodiment, the second interconnection structure includes multiple interconnection lines 180 and through-via interconnection structures 190 for connecting interconnection lines 180 of adjacent layers. It should be noted that the interconnection lines 180 exposed on the surface of the package substrate 170 may be used as solder pads. In other embodiments, the second interconnection structure may include interconnection through-via structures running through the package substrate.

In the present embodiment, the second surface 100B of the photonic interposer 100 is bonded on the package substrate 170 through the second conductive connection element 130, the second conductive connection element 130 electrically connects the photonic interposer 100 with the package substrate 170. In some embodiments, the second conductive connection element 130 electrically connects the first interconnection structure 110 in the photonic interposer 100 and the second interconnection structure in the package substrate 170.

It should be noted that since the photonic interposer 100 is temporarily bonded on the carrier board 101 (as shown in FIG. 13), after exposing the cavity 313, before bonding the second surface 100B of the photonic interposer 100 on the package substrate 170, the package method further includes: separating the carrier board 101 and the photonic interposer 100.

In some embodiments, debonding is performed to remove the carrier board 101 and the temporary bonding layer 102 (as shown in FIG. 13).

Referring to FIG. 16, FIG. 16 is a cross-sectional schematic diagram based on FIG. 15, the package method further includes: forming a second underfill layer 230 between the photonic interposer 100 and the package substrate 170, the second underfill layer 230 also covers the sidewalls of the second conductive connection element 130.

As an example, the material of the second underfill layer 230 includes epoxy resin, so that it can serve for mitigating stress impact.

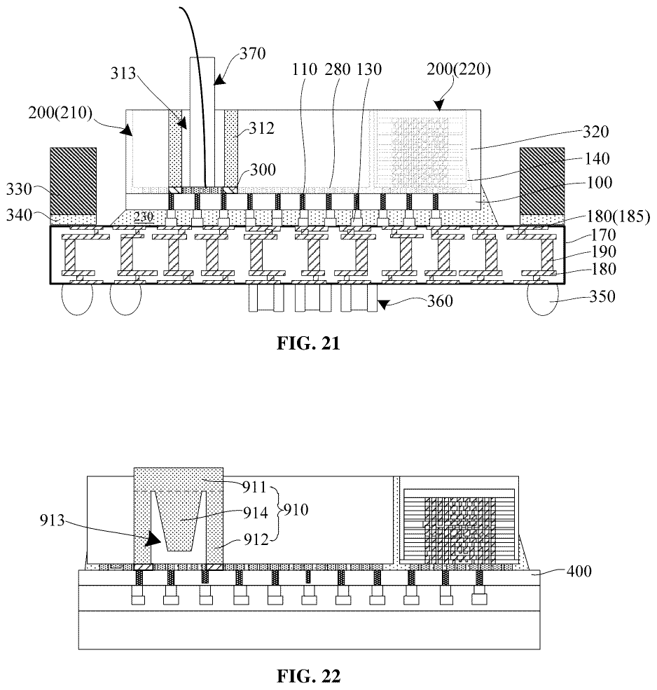

Referring to both FIGS. 20 and 21, FIG. 20 is a top view schematic diagram, and FIG. 21 is a cross-sectional schematic diagram of FIG. 20 at position A1-A2, after exposing the cavity 313, the package method further includes: installing an optical fiber structure 370 in the cavity 313.

The optical fiber in the optical fiber structure 370 is coupled with the photonic device in the photonic interposer 100 to achieve optical communication.

As an example, the optical fiber structure 370 may be fixed on the solder pad area in the optical coupling area 150 through an adhesive layer (e.g., optical adhesive).

As an example, the optical fiber structure 370 may be an optical fiber array unit.

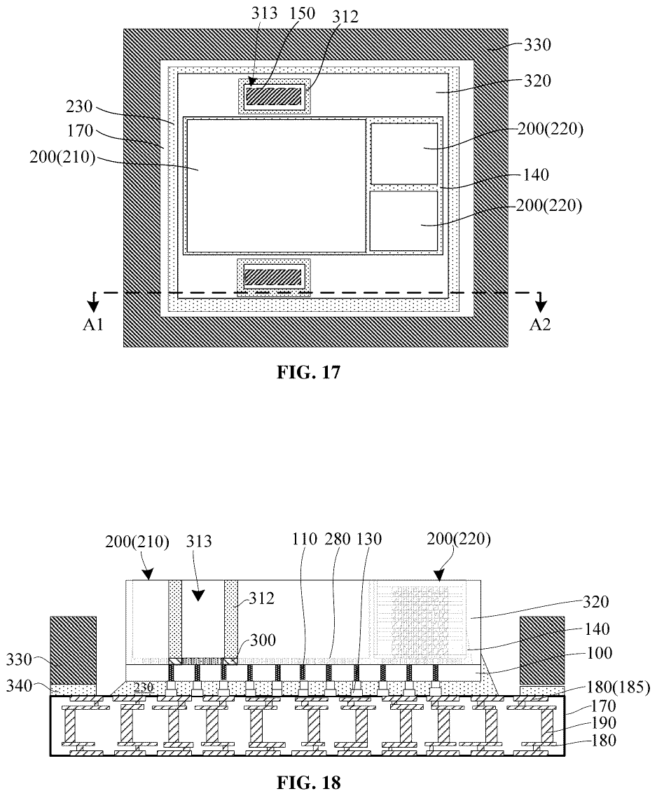

Referring to both FIGS. 17 and 18, FIG. 17 is a top view schematic diagram, FIG. 18 is a cross-sectional schematic diagram of FIG. 17 at position A1-A2; after bonding the second surface 100B of the photonic interposer 100 on the package substrate 170, and before installing the optical fiber structure 370 in the cavity 313, the package method further includes: arranging, on the package substrate 170, a stiffener ring 330 surrounding the photonic interposer 100.

The stiffener ring 330 helps to reduce the probability of the occurrence of warping problems in the package substrate 170 and is also conductive to improving the mechanical strength of the package structure; furthermore, the stiffener ring 330 surrounds the photonic interposer 100, accordingly, it is also beneficial to provide certain protection for the photonic interposer 100 and the chip 200.

It should be noted that first arranging the stiffener ring 330 on the package substrate 170 improves the flatness of the package substrate 170; correspondingly, when subsequently installing the optical fiber structure 370 in the cavity 313, it is conductive to improving the installation reliability of the optical fiber structure 370 on the photonic interposer 100.

As an example, the stiffener ring 330 is located at the edge of the package substrate 170, thereby enhancing the effect of improving the warping problem and providing sufficient space for the installation of the photonic interposer 100.

As an example, the projection shape of the stiffener ring 330 on the package substrate 170 is square. In other embodiments, the projection shape of the stiffener ring may also be other shapes (e.g., circular, octagonal, etc.).

In the present embodiment, the material of the stiffener ring 330 includes metal. The stiffener ring 330 using metal material also facilitates improving heat dissipation performance of the package structure. As an example, the material of the stiffener ring 330 may include copper, iron, nickel, stainless steel, nickel-iron alloy, etc.

In the present embodiment, the connection layer 300 located between the first surface 100A and the cap 310 is used as the first connection layer, the second connection layer 340 is then used to fix the stiffener ring 330 on the package substrate 170.

The second connection layer 340 is used to fix the stiffener ring 330 on the package substrate 170 and improve the bonding strength between the stiffener ring 330 and the package substrate 170.

In the present embodiment, the second connection layer 340 may be an adhesive layer. The material of the adhesive layer includes silicon-based adhesive layer, polyimide-based adhesive layer, epoxy resin-based adhesive layer, or polyurethane-based adhesive layer.

As an example, the material of the stiffener ring 330 is metal, so the second connection layer 340 may be a thermally conductive adhesive layer to improve the heat dissipation performance of the package structure.

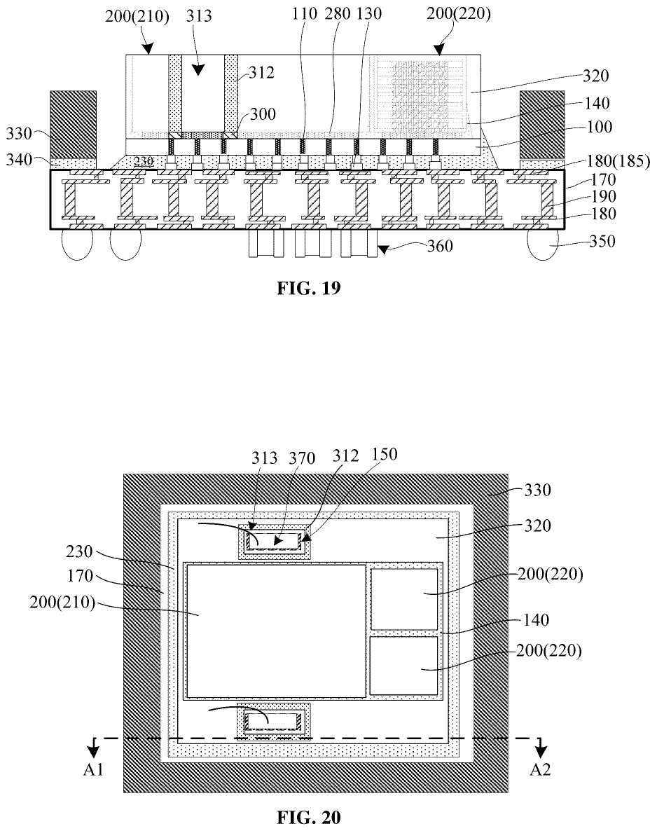

Referring to FIG. 19, FIG. 19 is a cross-sectional schematic diagram based on FIG. 18, after arranging the stiffener ring 330 surrounding the photonic interposer 100 on the package substrate 170, and before installing the optical fiber structure 370 in the cavity 313, the package method further includes: forming a third conductive connection element 350 on the surface of the package substrate 170 facing away from the photonic interposer 100, the third conductive connection element 350 electrically connects the package substrate 170.

In some embodiments, the third conductive connection element 350 electrically connects the second interconnection structure in the package substrate 170.

The third conductive connection element 350 is used to achieve electrical connection between the package substrate 170 and other circuits. For example, the package substrate 170 is subsequently assembled onto a PCB board through the third conductive connection element 350.

It should be noted that first arranging the stiffener ring 330 on the package substrate 170 improves the flatness of the package substrate 170, correspondingly, it is conductive to improving the reliability of the electrical connection between the third conductive connection element 350 and the package substrate 170.

In the present embodiment, the third conductive connection element 350 is a bump, such as a solder ball. The third conductive connection element 350 may be made of materials with good electrical conductivity, such as one or more of copper, aluminum, gold, nickel, silver, palladium, and tin.

Continuing with reference to FIG. 19, after arranging the stiffener ring 330 surrounding the photonic interposer 100 on the package substrate 170, and before installing the optical fiber structure 370 in the cavity 313, the package method further includes: bonding a passive device 360 on the surface of the package substrate 170 facing away from the photonic interposer 100.

By integrating passive device 360 in the package structure, it helps to improve the performance of the package structure.

Passive device 360 may include a capacitor, an inductor, a resistor, etc., which play a specific role in the operation of optoelectronic system.

It should be noted that first arranging the stiffener ring 330 on the package substrate 170 improves the flatness of the package substrate 170, which correspondingly helps improve the bonding reliability of the passive device 360.

It should also be noted that the passive device 360 is located on the surface of package substrate 170 facing away from the photonic interposer 100, which can fully utilize the area of the package substrate 170, and helps to reduce the lateral dimensions of the package structure.

Moreover, by first forming the third conductive connection element 350 on the package substrate 170 and bonding the passive device 360 on the package substrate 170 and then installing the optical fiber structure 370 in the cavity 313, on the one hand, it is conducive to providing convenience for forming the third conductive connection element 350 and bonding of the passive device 360, and on the other hand, it is also conducive to improving the installation reliability of the optical fiber structure 370 on the photonic interposer 100 and reducing the probability of damage to the optical fiber structure 370.

FIGS. 22 to 24 are schematic diagrams corresponding to each step in another embodiment of the package method of the present disclosure.

The similarities between the present embodiment and the aforementioned embodiments will not be repeated herein. The difference between the present embodiment and the aforementioned embodiments lies in: as shown in FIG. 22, in the step of arranging a cap 910 covering over the optical coupling area (not labeled) on the first surface (not labeled) of the photonic interposer 400, the cap 910 further includes a protruding part 914 protruding from the top cover 911 and facing the photonic interposer 400, there is a gap between the protruding part 914 and the optical coupling area.

In the present embodiment, the cap 910 includes the top cover 911, the protective ring 912 located between the top cover 911 and the photonic interposer 400, and the protruding part 914 protruding from the top cover 911, the solid part of the cap 910 is increased through the protruding part 914, which is conducive to improving the mechanical strength of the cap 910.

Moreover, there is a gap between the protruding part 914 and the optical coupling area, thereby avoiding the protruding part 914 contacting the optical coupling area, thus reducing the probability of damage to the optical coupling area caused by the cap 910.

Additionally, the top cover 911 and the protective ring 912 enclose the cavity 913, after subsequently separating the protruding part 914 and the top cover 911, the entire space of the cavity 913 can be exposed.

In the present embodiment, the material of the cap 910 is epoxy molding compound, thereby reducing the difficulty of forming the protruding part 914.

In the present embodiment, the maximum lateral dimension of the protruding part 914 is less than the lateral dimension of the cavity 913, thereby reducing the difficulty of subsequently removing the protruding part 914. Herein, lateral is parallel to the first surface of photonic interposer 400.

In one embodiment, the lateral dimensions of protruding part 914 decrease along the direction of the top cover 911 towards photonic interposer 400, thereby further reducing the difficulty of subsequently removing the protruding part 914. For example, the shape of the protruding part 914 is a frustum.

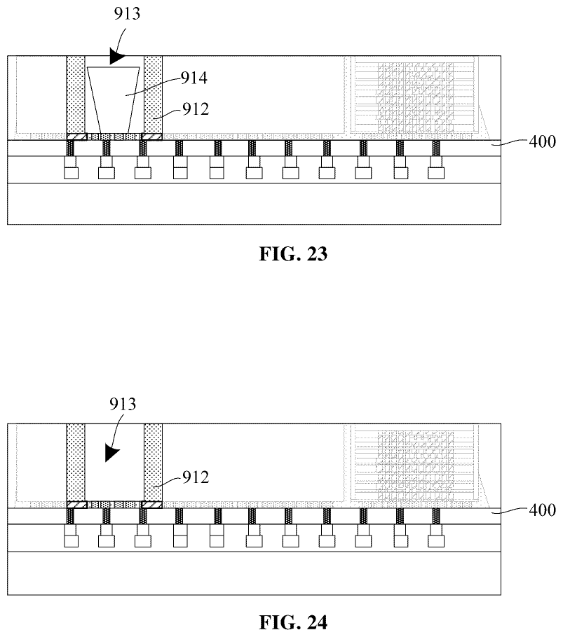

Referring to FIG. 23, in the step of the thinning treatment of the cap 910, the top cover 611 is removed and the protective ring 612 is retained.

The top cover 911 is connected with the protruding part 914; by removing the top cover 911, the top cover 911 and the protruding part 914 are correspondingly separated; at this time, the protruding part 914 is still located in the cavity 913 and consistently shields the optical coupling area throughout the thinning treatment, thereby preventing contaminants from polluting the optical coupling area.

Therefore, referring to FIG. 24, after thinning the cap 910, the step of exposing the cavity 913 further includes: removing the protruding part 914 remaining in the cavity 913.

The protruding part 914 remaining in the cavity 913 is removed to expose the optical coupling area.

In the present embodiment, after thinning the cap 910, the protruding part 914 falls to the bottom of the cavity 913, therefore, the method for removing the protruding part 914 remaining in the cavity 913 includes: inverting the photonic interposer 400.

After inverting the photonic interposer 400, due to the end of protruding part 914 facing away from the photonic interposer 400 being suspended, it can fall off the cavity 913.

It should be noted that the remaining steps may be the same as the aforementioned embodiments, for the specific description of the package method in the present embodiment, reference can be made to the relevant content in the aforementioned embodiments, which will not be repeated herein.

It should also be noted that the package structure of the aforementioned embodiments may be obtained using the package method of any one of the aforementioned embodiments, or using other package methods, for the specific descriptions of the package methods in the aforementioned embodiments, reference can be made to the relevant descriptions of the part of the package structure.

Although the present disclosure is disclosed as above, the present disclosure is not limited to this. Any skilled in the art may also make various changes and modifications without departing from the spirit and scope of the present disclosure, therefore the scope of protection of the present disclosure should be based on the scope defined by the claims.

What is claimed is:

1. A package structure, comprising:
a photonic interposer configured to be integrated with a photonic device, wherein a first surface of the photonic interposer comprises an optical coupling area;
a chip bonded on the first surface and arranged spaced apart from the optical coupling area, wherein the chip is electrically connected to the photonic interposer;
a protective ring located on the first surface and surrounding the optical coupling area, wherein the protective ring comprises a cavity exposing the optical coupling area; and
a molding layer located on the first surface, on a side of the chip, and outside of the cavity, the molding layer covers side walls of the chip and outer walls of the protective ring.

2. The package structure according to claim 1, further comprising: an optical fiber structure installed in the cavity.

3. The package structure according to claim 1, further comprising: a connection layer located between the first surface and the protective ring, wherein the connection layer comprises an epoxy resin layer or an adhesive layer.

4. The package structure according to claim 1, wherein a material of the protective ring comprises one or more of metal, epoxy molding compound, ceramic, and silicon.

5. The package structure according to claim 1, wherein a top of the molding layer, a top of the protective ring, and a top of the chip are all flush with each other.

6. The package structure according to claim 1, further comprising:
a package substrate, wherein a second surface of the photonic interposer is bonded on the package substrate, the photonic interposer is electrically connected to the package substrate, and the second surface is arranged facing away from the first surface.

7. The package structure according to claim 6, further comprising: a stiffener ring located on the package substrate and surrounding the photonic interposer, wherein a material of the stiffener ring comprises metal.

8. The package structure according to claim 1, wherein the chip comprises one or more of an Application-Specific Integrated Circuit (ASIC) chip, a High Bandwidth Memory (HBM) chip, a Central Processing Unit (CPU) chip, a Graphics Processing Unit (GPU) chip, and a Field-Programmable Gate Array (FPGA) chip.

9. A package method, comprising:
providing a photonic interposer configured to be integrated with a photonic device, wherein a first surface of the photonic interposer comprises an optical coupling area;
bonding a chip on the first surface, wherein the chip is arranged spaced apart from the optical coupling area, and the chip is electrically connected to the photonic interposer;
arranging, on the first surface, a cap covering over the optical coupling area, wherein the cap comprises a cavity, and a projection of the cavity on the photonic interposer covers the optical coupling area;
forming a molding layer on the first surface, a side of the chip, and a side of the cap, wherein the molding layer covers side walls of the chip and side walls of the cap; and
after forming the molding layer, thinning the cap to expose the cavity.

10. The package method according to claim 9, wherein when arranging, on the first surface, a cap covering over the optical coupling area, the cap is fixed on the first surface using a connection layer.

11. The package method according to claim 10, further comprising: forming the connection layer surrounding the optical coupling area on the first surface, and the cap is fixed on the connection layer.

12. The package method according to claim 9, wherein when arranging, on the first surface, a cap covering over the optical coupling area, a material of the cap comprises one or more of metal, epoxy molding compound, ceramic, and silicon.

13. The package method according to claim 9, wherein when arranging, on the first surface, a cap covering over the optical coupling area, the cap comprises a top cover and a protective ring located between the top cover and the photonic interposer, and the top cover and the protective ring enclose the cavity; and
when thinning the cap, the method further comprises removing the top cover and retaining the protective ring.

14. The package method according to claim 13, wherein when arranging, on the first surface, a cap covering over the optical coupling area, the cap further comprises a protruding part protruding from the top cover and facing the photonic interposer, and a gap is provided between the protruding part and the optical coupling area; and
after thinning the cap, exposing the cavity further comprises: removing the protruding part remaining in the cavity.

15. The package method according to claim 14, wherein the removing the protruding part remaining in the cavity further comprises: inverting the photonic interposer.

16. The package method according to claim 14, wherein a maximum lateral dimension of the protruding part is smaller than a lateral dimension of the cavity.

17. The package method according to claim 9, wherein when forming a molding layer on the first surface, a side of the chip, and a side of the cap, the molding layer covers a top of the chip and a top of the cap, and
the method further comprises: sequentially performing a thinning treatment on the molding layer and the cap to expose the cavity, and making the top of the molding layer flush with the top of the chip.

18. The package method according to claim 9, wherein after exposing the cavity, the method further comprises: installing an optical fiber structure in the cavity.

19. The package method according to claim 18, wherein after exposing the cavity and before installing the optical fiber structure in the cavity, the method further comprises:
bonding a second surface of the photonic interposer on a package substrate, wherein the photonic interposer is electrically connected with the package substrate, and the second surface is arranged facing away from the first surface,
wherein when providing a photonic interposer integrated with a photonic device, the photonic interposer is temporarily bonded on a carrier board, and the first surface of the photonic interposer faces away from the carrier board; and
wherein after exposing the cavity and before bonding the second surface of the photonic interposer on the package substrate, the package method further comprises: separating the carrier board and the photonic interposer,
wherein after bonding the second surface of the photonic interposer on the package substrate, and before installing the optical fiber structure in the cavity, the package method further comprises: arranging, on the package substrate, a stiffener ring surrounding the photonic interposer.

20. The package method according to claim 9, wherein when arranging a chip on the first surface, the chip comprises one or more of an Application-Specific Integrated Circuit (ASIC) chip, a High Bandwidth Memory (HBM) chip, a Central Processing Unit (CPU) chip, a Graphics Processing Unit (GPU) chip, and a Field-Programmable Gate Array (FPGA) chip.
